(19) United States
(12) Patent Application Publication
(10) Pub. No.: US 2002/0126720 A1
(43) Pub. Date: Sep. 12, 2002

(54) Device structure and method for fabricating semiconductor lasers

(76) Inventor: Ying-Jay Yang, Taipei (TW)

Correspondence Address: RABIN & CHAMPAGNE, PC, 1101 14TH STREET, NW, SUITE 500, WASHINGTON, DC, 20005, US

(21) Appl. No.: 09/799,703

(22) Filed: Mar. 7, 2001

(51) Int. Cl. H01S 5/00; H01S 3/08

(52) U.S. Cl. 372/45; 372/96

(57) ABSTRACT

A vertical-cavity surface-emitting laser structure and a method for fabricating the same are provided. The device comprises a structure which consists of: a substrate; a multi-layered structure stacked over the substrate, which consists of a bottom distributed Bragg reflector, a bottom cladding or spacer layer, a light-emitting active layer, a top cladding or spacer layer, a top distributed Bragg reflector (DBR). The method for fabricating the device involves: forming an absorber with an aperture in a part of the multi-layered structure; forming an active region with its center aligned with the absorber aperture on the light-emitting active layer; and forming a p-electrode and an n-electrode on a p-type and an n-type layers respectively. The device structure and fabrication method is to provide a vertical-cavity surface-emitting laser that can operate in a stable single-mode with a sufficient output power and high yield production.

### BACKGROUND OF THE INVENTION

1. Field of the Invention

The present invention relates to semiconductor lasers and methods for fabricating the same, and more particularly relates to semiconductor vertical-cavity surface-emitting lasers and methods useful for fabricating the same. Description of the Relate Art In recent years, vertical-cavity surface-emitting lasers (VCSELs)[Koyama et al “Room-temperature continuous wave lasing characteristics of a GaAs vertical-cavity surface-emitting laser,” Appl. Phys. Lett. vol. 55, 221-222, 1989] have become important light sources for the various optical communication and storage systems due to their unique features, such as the low threshold current, single longitudinal mode operation, and low divergent beam. Particularly, vertical-cavity surface-emitting lasers with a stable single-mode operation that operates in both a single longitudinal mode and a single transverse mode are highly desirable for high speed long haul communication to minimize dispersion effects, for wavelength-division-multiplex (WDM) system to avoid interchannel crosstalk, and for optical storage and printing systems to obtain a single circular pattern. Here we define the stable single-mode operation as a lasing with a single-mode that can maintain over the entire drive current range above the threshold current. The vertical-cavity surface-emitting lasers typically operate in a single longitudinal mode due to their built-in distributed Bragg reflectors (DBRs) and the wide mode spacing (30-40 nm). However, the single transverse mode is more difficult to achieve because it requires either a good current confinement scheme in transverse direction to form a single transverse mode active region with diameter usually less than ˜5 μm, or an optical structure in the cavity for single transverse mode selection. In the prior art, although various vertical-cavity surface-emitting laser (VCSEL) structures have been fabricated, only few devices exhibited stable single-mode operation. The etched mesa vertical-cavity surface-emitting laser (VCSEL) [Jewell et al “Low threshold electrically pumped vertical-cavity surface-emitting microlaser,” Electron. Lett., vol. 25, pp. 1123-1125, 1989] using a mesa structure to confine the injection current and optical field usually operates in multimode due to the strong index-guided structure. The ion-implanted vertical-cavity surface-emitting laser (VCSEL) [Geel et al “Low threshold planarized vertical-cavity surface-emitting lasers,” IEEE Photon. Technol. Lett., vol. 2, pp. 234-236,1990] with active regions defined by ion implantation can maintain a single-mode operation only at lower current levels, and exhibits multimode at higher current levels. Although the vertical-cavity surface-emitting laser (VCSEL) with a passive antiguide region [Wu et al “High-yield processing and single-mode operation of passive antiguide region vertical-cavity lasers,” IEEE J. Select. Topics Quantum Electron. Vol. 3, pp-429-434, 1997] can operate in a stable single-mode, the device fabrication which requires a crystal regrowth is more complicated. The oxide-confined vertical-cavity surface-emitting laser (VCSEL) [Grabherr et al “Efficient single-mode oxide-confined GaAs VCSEL's emitting in the 850 nm wavelength regime,” IEEE Photon. Technol. Lett. vol. 9, pp. 1304-1306, 1997] requires an oxidation process to convert an AlAs layer to an AlOₓ layer forming an active region less than 3 μm diameter to have a stable single-mode operation. This laser structure demands a very critical control on both the epilayer growth to vertically position the AlOₓ layer close to a node of the optical standing-wave and the oxidation process to laterally oxidize the AlAs layer to a desired length within ˜1 μm accuracy. The vertical-cavity surface-emitting laser with an etched surface on the top side [Unold et al “Increased-area oxidized single-fundamental mode VCSEL with self-aligned shallow etched surface relief,” Electron. Lett., vol. 35, pp. 1340-1341, 1999] to suppress the higher-order modes can perform single-mode operation only up to five times threshold current, it also requires a critical control on the etched depth within a range of 50 nm (0.05 μm). The same inventor previously demonstrated that a vertical-cavity surface-emitting laser with a top selectively disordered mirror formed by zinc (Zn) diffusion through the entire (100%) top distributed Bragg reflector (DBR) [Dziura, T. G. Yang, Y. J., et al “Single mode surface emitting laser using partial mirror disordering,” Electron. Lett., vol. 29, pp. 1236-1237, 1993] can maintain stable single-mode operation, but the device suffers from a large optical loss due to the high hole concentration in the thick Zn diffusion region (>3 μm), resulting in a higher threshold current and a very low output power (<0.25 mW) which is insufficient for practical use. All of the abovementioned vertical-cavity surface-emitting laser structures and associated fabrication methods, though widely used, have exhibited either an unsatisfactory performance with an unstable single-mode operation or a high threshold current and an insufficient output power, or a great difficulty in fabrication, particularly for the large scale production. Consequently, there is a demand for a device that can operate in a stable single-mode with a sufficient output power (>1 mW) for most applications, and a fabrication method that is a relatively simple process with a high yield, and can be readily adopted by the conventional semiconductor technology and also compatible with the mass production.

### SUMMARY OF THE INVENTION

The purpose of the present invention is to provide a vertical-cavity surface-emitting laser that can operate in a stable single-mode with a sufficient output power useful for most applications, and a fabrication method that can be readily adopted by the conventional semiconductor technology and is compatible with the mass production. A vertical-cavity surface-emitting laser structure and a method for fabricating the same are provided. The vertical-cavity surface-emitting laser comprises an epilayer structure, which consists of:

a substrate;

a multi-layered structure stacked over the substrate, which consists of a bottom distributed Bragg reflector (DBR), a bottom cladding or spacer layer, a light-emitting active layer, a top cladding or spacer layer, a top distributed Bragg reflector (DBR).

The method for fabricating the vertical-cavity surface-emitting laser involves:

in a part of the laser multi-layers, forming an absorber with an aperture;

on the light-emitting active layer, forming an active region with its center aligned with the aperture of the absorber; and

on a p-type and an n-type layers, forming a p-electrode and an n-electrode respectively.

### BRIEF DESCRIPTION OF THE DRAWINGS

FIG. 1 is a cross-sectional view, schematically showing a vertical-cavity surface-emitting laser according to an embodiment of the invention, with an absorber formed in the distributed Bragg reflector and an active region formed by ion implantation.

FIG. 2 is a graph of the light output power versus current characteristics of the device of the present invention.

FIG. 3 is a graph of the emission spectra at different current levels of the device of the present invention.

FIG. 4 is a cross-sectional view, schematically showing a vertical-cavity surface-emitting laser according to an embodiment of the invention, with an absorber formed in the distributed Bragg reflector and an active region formed by oxidation.

### DETAILED DESCRIPTION OF THE PREFERRED EMBODIMENTS

In the present invention, the terms “vertical-cavity surface emitting laser”, “distributed Bragg reflector”, and “single transverse mode” are used in an ordinary sense in the field of semiconductors.

In the present invention, the term “stable single-mode operation” means that the laser devices operate in single-mode over the entire drive current range above the threshold current.

In the present invention, the term “absorber” means that the absorption coefficient of the corresponding region is at least 10/cm with respect to the light emitted from the active region of the device.

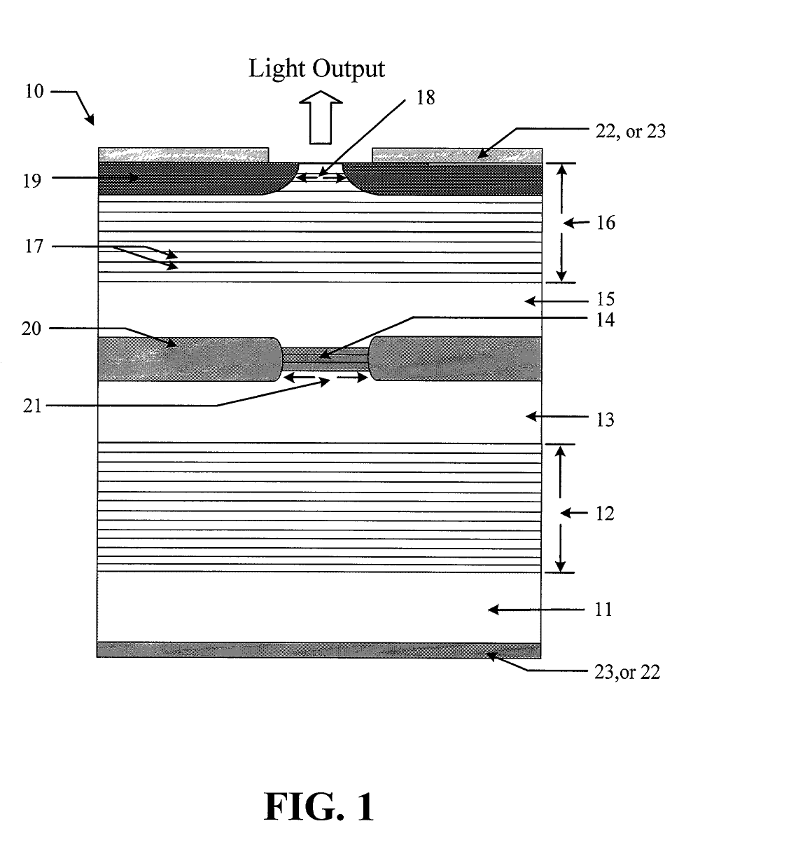

FIG. 1 schematically shows the cross-section of a vertical-cavity surface emitting laser (VCSEL) (10). It comprises of a substrate (11) and a multi-layered structure stacked over the substrate, which consists of a bottom distributed Bragg reflector (12), a bottom cladding or spacer layer (13), a light-emitting active layer (14) which can be of a single layer, or a quantum-well structure, a top cladding or spacer layer (15), a top distributed Bragg reflector (16).

Both the top and bottom distributed Bragg reflector (12, 16) are typically made of many pairs of alternate layers (17), such as GaAs/AlAs, InₓGa₁₋ₓAs_{y}P_{1-y}/InP, each alternate layer (17) has a thickness of a quarter of the corresponding lasing wavelength, and the pair number of alternate layers (17) is designed to be large enough to give a very high reflectivity (>99%) with respect to the lasing wavelength, usually it is preferably between 20 and 40. The pair of alternate layer (17) usually consists of an interface of grading composition.

In a part of the laser multi-layers a torus region is selectively heavily doped (>5×10¹⁸/cm³) with an aperture (18) that remains intact to form an absorber (19) for higher-order modes by using a conventional process, such as diffusion, implantation, or regrowth. The absorber (19) can be doped with a p-type dopant such as zinc (Zn), magnesium (Mg), beryllium (Be), strontium (Sr), or barium (Ba), or an n-type dopant such as silicon (Si), germanium (Ge), selenium (Se), sulfur (S), or tellurium (Te). The purpose of forming an absorber (19) with an aperture (18), which allows only the light of fundamental mode transmit through, is to suppress the lasing of higher-order modes other than the fundamental mode. To achieve this end, the aperture (18) is preferably to have a diameter or a longest diagonal between 1 and 8 μm, more preferably between 4 and 6 μm. The thickness of the absorber (19) will determine the absorption loss of the light passing through and the degree of the higher-order mode suppression. Since the part (<10%) of the fundamental mode light may also couple to the absorber (19) resulting in an absorption loss, the thickness of the absorber (19) needs to be optimized.

Therefore, to have an absorber (19) thick enough to suppress the higher-order mode but not to cause a significant absorption loss for the fundamental mode, the absorber thickness is preferably between 3 and 95%, more preferably between 10 and 50%, most preferably between 15 and 40%, of the thickness of the distributed Bragg reflector where the absorber (19) is usually located.

To reduce the absorption loss of the fundamental mode, the absorber (19) is preferably formed at the far end of the distributed Bragg reflector away from the light-emitting active layer (14).

Around the light-emitting active layer (14), a current confinement structure (20) is formed to confine the injection current in an active region (21) with its center aligned with the aperture (18) of the absorber (19), by using a conventional semiconductor process, such as implantation, diffusion, oxidation, or mesa etching. The diameter of the active region (21) is preferably between 1 and 50 μm, more preferably between 5 and 15 μm.

To form a p-n junction of the device, the semiconductor layers above and below the light-emitting active layer (14) are formed to be p- and n-typed, or n- and p-typed respectively.

A p-electrode (22) and an n-electrode (23) are formed on a p-type layer and an n-type layer of the laser structure respectively. An opening with its center aligned with the active region and the aperture of the absorber is formed on either the p- or n-electrode to allow the light emitted out.

In the present invention, the vertical-cavity surface-emitting laser (10) can be made of materials of semiconductor and dielectric systems, such as AlₓGa₁₋ₓAs, AlₓGa_{y}In_{1-x-y}As, InₓGa₁₋ₓAs_{y}P_{1-y}, AlₓGaIn_{1-x-y}P/As, InₓGa_{y}N_{1-x-y}As, GaₓAl_{y}In_{1-x-y}N, GaAsₓSb₁₋ₓ, ZnₓCd₁₋ₓS_{y}Se_{1-y}, SiO₂/Si₃N₄, SiO₂/TiO₂, or Si/SiO₂. The lasing wavelength of the vertical-cavity surface-emitting laser (10) is mainly determined by the material and structure used.

The present invention will be described below by way of the following examples.

### EXAMPLE 1

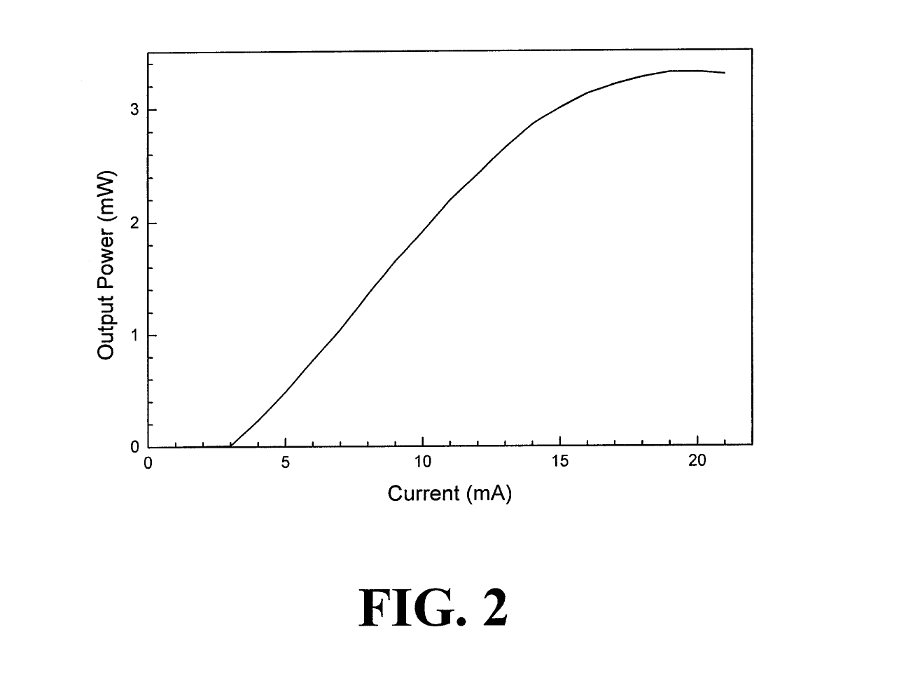

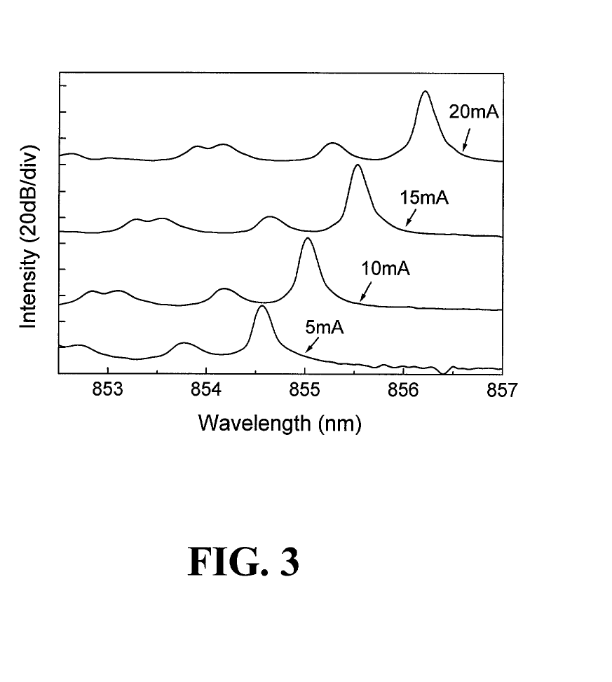

The wafer used for the fabrication of a single-mode 850 nm vertical-cavity surface-emitting laser (VCSEL) consisted of a typical VCSEL epilayer structure, a three GaAs/AIGaAs multiquantum wells (MQW) with the top and bottom cladding layers sandwiched by a 30-pair n-type and a 20-pair p-type Al_{0 12}Ga_{0 88}As/Al_{0 9}Ga_{0 1}As layers with interfaces of grading composition. The completed device shown in FIG. 1 was fabricated as follows: First a Si₃N₄ mask with 5 μm diameter circles was formed on the sample, then the masked sample with a Zn₂As₃ source was sealed in a vacuumed quartz ampoule and put into a 650° C. furnace for 8 min short time Zn diffusion. It was intended to have a Zn diffused region with a thickness less than 0.5 μm, corresponding to 15% of the top p-type distributed Bragg reflector multilayer, outside the Si₃N₄ masked area to form a higher-order mode absorber. Following the Zn diffusion the sample was selectively implanted with proton of an energy of 300 keV and a dosage of 1×10¹⁴, using a 6 μm thick photoresist layer with a 15 μm diameter as an implanted mask. After the photoresist layer was stripped off, a Cr/Au film with a 15×15 μm² emitting window was deposited on the top and a Ge/Au film was deposited on the backside of the sample to form a p- and an n-type electrodes respectively. FIG. 2 shows the typical light output power and voltage versus current characteristics of a fabricated device. The performance with a low threshold current of 3.0 mA and a maximum output power of >3.0 mW was obtained, which was substantially better than that of the vertical-cavity surface-emitting laser with a thick zinc diffusion region (>3.0 μm, 100% of the top distributed Bragg reflector), in which typically the threshold current was >8 mA and the output power was only 0.25 mW. FIG. 3 shows the corresponding emission spectra of the device at different current levels, which indicates that the device operates in a stable single-mode with a higher-order mode suppression ratio better than 40 dB up to the maximum drive current where the light output saturates. The number of laser devices fabricated from the wafer was about 12,000. The yield of better than 95% stable single-mode laser devices was obtained. Thus, it was confirmed that, according to the present invention, a vertical-cavity surface-emitting laser with a stable single-mode operation and a sufficient output power (>1 mW) and a fabricating method to produce good quality devices with a high yield are provided.

### EXAMPLE 2

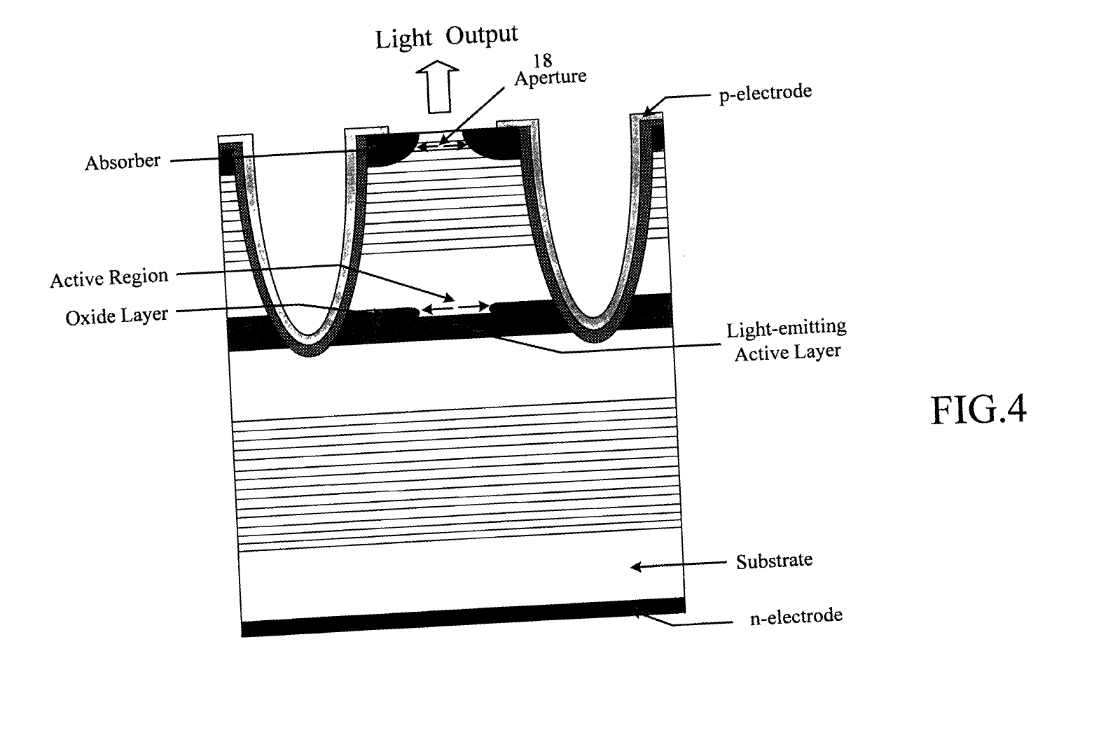

The same wafer as in Example 1 was used to fabricate a single-mode 850 nm vertical-cavity surface-emitting laser. The completed device shown in FIG. 4 was fabricated as follows: First a Si₃N₄ mask with 5 μm diameter circles was formed on the sample, then a Zn(3000 A)/Au(1000 A) film was deposited on the masked sample, which was put into a 650° C. furnace for 10 min open-tube Zn diffusion. It was intended to have a Zn diffused region with a thickness <0.8 μm, corresponding to 25% of the top p-type distributed Bragg reflector, outside the Si₃N₄ masked area to form a higher-order mode absorber. After the Zn diffusion the sample was etched to form mesa/moat structure. The moats were etched with ˜1 μm deeper than the light-emitting active layer to expose the AlGaAs layer and isolate the devices electrically. Then the sample was put in a 415° C. furnace with 90° C. H₂O vapor flowing to oxidize the exposed AlGaAs to form a current confined active region. Following the oxidation a 2000 Å SiO₂ film was deposited over the entire sample and a 30×30 μm² square window was opened on the top of mesa. At final step a Cr/Au film with a 15×15 μm² window was deposited on the top and a Ge/Au film was deposited on the backside of the sample to form a p- and an n-type contacts respectively. The performances of the vertical-cavity surface-emitting laser fabricated were substantially the same as those of the devices of Example 1. The yield was also the same as in Example 1.

### EXAMPLE 3

The same wafer as in Example 1 was used to fabricate a single-mode 850 nm vertical-cavity surface-emitting laser. The completed device essentially same as that shown in FIG. 1 was fabricated as follows: First a 3000 A thick Au film with 5 μm diameter circles was formed photolithographically on the sample, then the masked sample was selectively implanted with Zn of an energy of 2.5 MeV and a dosage of 1×10¹⁵/cm². After the implantation the sample was annealed at 900° C. for 30 sec to activate the implanted Zn forming a higher-order mode absorber. Following the Zn implantation and annealing the sample was selectively implanted with proton of an energy of 300 keV and a dosage of 3×10¹⁴, using a 6 μm thick photoresist layer with a 15 μm diameter as an implanted mask. After the photoresist layer was stripped off, a Cr/Au film with a 15×15 μm² emitting window was deposited on the top and a Ge/Au film was deposited on the backside of the sample to form a p- and an n-type electrode respectively. The performances of the vertical-cavity surface-emitting laser fabricated were substantially the same as those of the devices of Example 1. The yield was also the same as in Example 1.

### EXAMPLE 4.

The wafer for the fabrication of a single-mode 1.3 μm vertical-surface emitting-laser (VCSEL) consisted of a typical VCSEL epilayer structure, a three InGaAsP/InP multiquantum wells (MQW) with the top and bottom cladding layers sandwiched by a 40-pair n-type and a 35-pair p-type InGaAsP/InP layers with interfaces of grading composition. The completed device was fabricated as follows: First a Si₃N₄ mask with 5 μm diameter circles was formed on the sample, then the masked sample with a Zn₂As₃ source was sealed in a vacuumed quartz ampoule and put into a 650° C. furnace for 15 min Zn diffusion. It was intended to have a Zn diffused region with a thickness less than 1.5 λm, corresponding to 20% of the top p-type distributed Bragg reflector multilayer, outside the Si₃N₄ masked area to form a higher-order mode absorber.

Following the Zn diffusion the sample was selectively implanted with proton of energy 650 KeV and a dosage of 1×10¹⁴, using a 10 μm thick photoresist layer with a 15 μm diameter as an implanted mask. After the photoresist layer was stripped off, a Ti/Pt/Au film with a 15×15 μm² emitting window was deposited on the top and a Ni/AuGe/Ni/Au film was deposited on the backside of the sample to form a p- and an n-type electrode respectively.

What is claimed is:

1. A vertical-cavity surface-emitting laser comprises:
a substrate;
a multi-layered structure stacked over the substrate, which consists of a bottom distributed Bragg reflector (DBR), a bottom cladding or spacer layer, a light-emitting active layer, a top cladding or spacer layer, a top distributed Bragg reflector (DBR);
an absorber with an aperture formed in a part of said multi-layered structure, and
comprising a thickness of 3% to 95% of said bottom or top distributed Bragg reflector (DBR);
an active region with its center aligned with said aperture of said absorber formed on said light-emitting active layer; and
a p-electrode and an n-electrode formed on a p-type and an n-type layer respectively.

2. The device according to claim 1, wherein said absorber with an aperture is formed of a heavily doped torus region with a dopant concentration larger than 5×10^{15/cm}³.

3. The device according to claim 1, wherein said aperture of said absorber has a diameter or a longest diagonal of 1 to 8 μm, or an area of 1 to 60 μm².

4. The device according to claim 2 wherein said dopant is formed of zinc (Zn), magnesium (Mg), beryllium (Be), strontium (Sr), barium (Ba), cadmium (Cd), silicon (Si), germanium (Ge), tin (Sb), selenium (Se), sulfur (S), or tellurium (Te).

5. The device according to claim 1, wherein said active region has a diameter or a longest diagonal of 5 to 50 μm or an area of 20 to 2000 μm².

6. The device according to claim 1, wherein said bottom distributed Bragg reflector and said bottom cladding or spacer layer are p-typed, and said top distributed Bragg reflector and said top cladding or spacer layer are n-typed.

7. The device according to claim 1, wherein said bottom distributed Bragg reflector and said bottom cladding or spacer layer are n-typed, and said top distributed Bragg reflector and said top cladding or spacer layer are p-typed.

8. The device according to claim 1, wherein said substrate is semiconductor material.

9. The device according to claim 1, wherein the layer of said multi-layered structure stacked over substrate is formed of either semiconductor or dielectric material.

10. The device according to claim 1, wherein said active region is confined laterally by insulating layers formed by ion implantation.

11. The device according to claim 1, wherein said active region is confined laterally by insulating layers formed by oxidation.

12. The device according to claim 1, wherein said active region is confined by a mesa structure.
